(19) United States
(12) Patent Application Publication
(10) Pub. No.: US 2026/0173607 A1
(43) Pub. Date: Jun. 18, 2026

(54) TILED DISPLAY

(71) Applicant: AUO Corporation, Hsinchu City (TW)

(72) Inventors: Hong-Sian CHI, Hsinchu City (TW); Yi-Fu Ou, Hsinchu City (TW); Yung-Chih Chen, Hsinchu City (TW); Ssu-Hsien Chih, Hsinchu City (TW); Yu-Chieh Lin, Hsinchu City (TW)

(21) Appl. No.: 19/416,589

(22) Filed: Dec. 11, 2025

Related U.S. Application Data
(60) Provisional application No. 63/733,464, filed on Dec. 13, 2024.

(30) Foreign Application Priority Data
Mar. 12, 2025 (TW) 114109173

(51) Int. Cl. H10H 29/14

(52) U.S. Cl. CPC H10H 29/142

(57) ABSTRACT

A tiled display includes: a plurality of display panels, wherein a tiling seam is located between the display panels. At least one of the display panels includes: a plurality of main pixels located in an active area having a plurality of first unit regions arranged in an array, wherein N main pixels are located in each of the first unit regions; and a plurality of edge effective pixels located in an edge area having a plurality of second unit regions arranged in an array, wherein the edge area is between the active area and the tiling seam, M edge effective pixel or pixels are located in each of the second unit regions, N is greater than M, each of the first unit regions and each of the second unit regions have a substantially identical area and a substantially identical brightness, and the substantially identical brightness is not zero.

This application claims the benefit of U.S. provisional patent application Ser. No. 63/733,464 filed Dec. 13, 2024 and Taiwan application Serial No. 114109173, filed Mar. 12, 2025, the disclosure of which are incorporated by reference herein in its entirety.

### TECHNICAL FIELD

The disclosure relates to a tiled display.

### BACKGROUND

When multiple displays are tiled together, discontinuities may occur at the boundaries, resulting in visual discontinuity in the displayed image. Whether for small-sized or large-sized displays, when multiple display panels are tiled together, dark regions may appear at the tiling boundaries, causing image discontinuity and degraded visual performance.

The main reasons for the tiling issue are as follows. (1) Mechanical width of the display: The frame of the display occupies physical space, making truly seamless tiling impossible between two displays. (2) Glass cutting and assembly tolerances: During manufacturing, slight deviation in glass cutting or assembly may result in gaps or misalignment when displays are tiled. (3) Differences in pixel pitches: If two adjacent display panels have different pixel pitches, the visual presentation at the tiling boundary will vary, leading to inconsistency.

Existing solutions are: (1) Keeping the tiling seam: directly accepting the presence of the seam without additional processing; (2) Reducing the border width (near-zero border): minimizing the frame width of the display so that the seam becomes extremely narrow after tiling; and (3) Without displaying images or displaying a black background at the tiling boundary: avoiding visual discontinuity by not displaying images or displaying a black background.

Although these methods can reduce the impact of tiling issues, achieving “seamless tiling” remains challenging.

### SUMMARY

The disclosure provides a tiled display which can reduce visual discontinuity.

According to at least one embodiment, a tiled display is provided. The tiled display includes display panels, wherein a tiling seam is located between the display panels. Each or at least one of the display panels includes main pixels and edge effective pixels. Main pixels are located in an active area having first unit regions arranged in an array. N main pixels are located in each of the first unit regions. N is a positive integer. Edge effective pixels are located in an edge area having second unit regions arranged in an array, and M edge effective pixel or pixels are located in each of the second unit regions. M is a positive integer and N is greater than M. The edge area is between the active area and the tiling seam. Each of the first unit regions and each of the second unit regions have a substantially identical area and a substantially identical brightness, and the substantially identical brightness is not zero.

According to at least one embodiment, a tiled display is provided. The tiled display comprises: a first display panel and a second display panel, wherein a tiling seam is located between the first display panel and the second display panel. Each of the first display panel and the second display panel comprises: a plurality of main pixels located in an active area having a plurality of first unit regions arranged in an array, wherein N main pixels are located in each of the first unit regions, and N is a positive integer; and a plurality of edge effective pixels located in an edge area having a plurality of second unit regions arranged in an array, wherein the edge area is between the active area and the tiling seam, M edge effective pixel or pixels are located in each of the second unit regions, M is a positive integer, N is greater than M, and each of the first unit regions and each of the second unit regions have a substantially identical area and a substantially identical brightness.

According to at least one embodiment, a tiled display is provided. The tiled display comprises: a plurality of display panels, wherein a tiling seam is located between the display panels. At least one of the display panels comprises: a plurality of main pixels located in an active area having a plurality of first unit regions arranged in an array, wherein N main pixels are located in each of the first unit regions, and N is a positive integer; and a plurality of edge effective pixels located in an edge area having a plurality of second unit regions arranged in an array, wherein the edge area is between the active area and the tiling seam, M edge effective pixel or pixels are located in each of the second unit regions, M is a positive integer, and each of the first unit regions and each of the second unit regions have a substantially identical area and a substantially identical brightness, wherein: a brightness of each of the main pixels of one of the first unit region is adjusted to be substantially identical; the second unit regions includes a first column, a second column and a third column, and the tiling seam, the first column, the second column, the third column and the active area are arranged in sequence along a first direction; in one of the second unit regions in the first column, a brightness of one of the edge effective pixels is adjusted to be 1, while a brightness of each of the remaining edge effective pixels is adjusted to be zero; in one of the second unit regions in the second column, a brightness of one of the edge effective pixels is adjusted to be X, 0<X<1, while a brightness of each of the remaining edge effective pixels is adjusted to be (1−X)/(M−1); and in one of the second unit regions in the third column, a brightness of one of the edge effective pixels is adjusted to be Y, 0<Y<1, while a brightness of each of the remaining edge effective pixels is adjusted to be (1−Y)/(M−1).

### BRIEF DESCRIPTION OF THE DRAWINGS

FIG. 1 illustrates a tiled display according to one embodiment of the present disclosure.

FIG. 2 illustrates a tiled display according to one embodiment of the present disclosure.

FIGS. 3A-3F illustrate tiled displays according to the embodiments of the present disclosure.

FIGS. 4A-4D illustrate brightness compensation according to the embodiments of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The technical terminology used in this specification refers to the customary terminology of the technical field to which the disclosure pertains. If certain terms are further explained or defined in this specification, the interpretation of such terms shall be based on the explanations or definitions provided herein. Each embodiment disclosed herein includes one or more technical features. To the extent practicable, a person having ordinary skill in the art may selectively implement part or all of the technical features of any embodiment, or selectively combine part or all of the technical features among these embodiments.

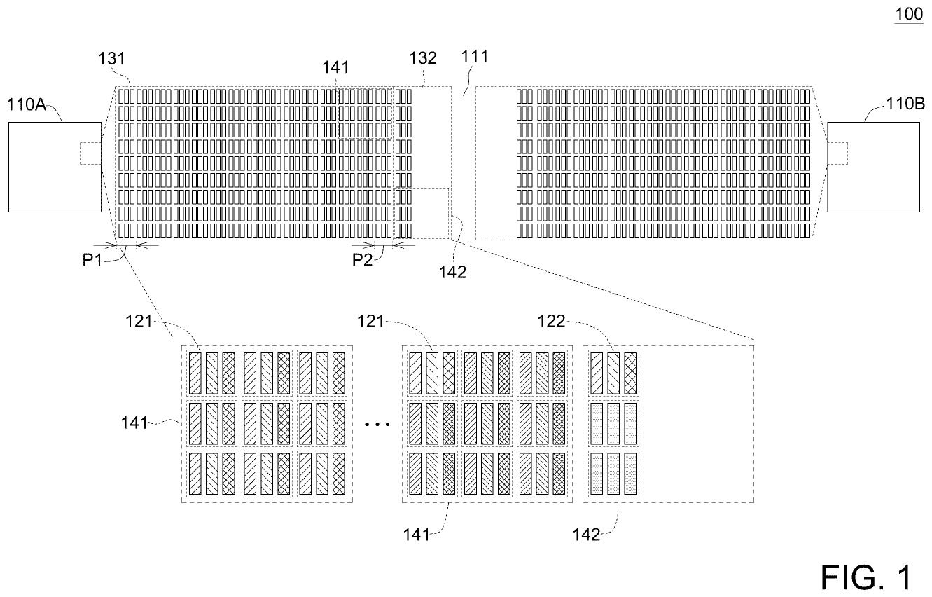

FIG. 1 illustrates a schematic diagram of a tiled display according to one embodiment of the present disclosure. As shown in FIG. 1, the tiled display 100 includes first display panel 110A and second display panel 110B, wherein a tiling seam 111 is located between the display panels 110A and 110B. The tiling seam 111 may correspond to a boundary line or area between the first display panel 110A and the second display panel 110B. Each of the display panels 110A and 110B includes main pixels 121 and edge effective pixels 122. The main pixels 121 are located in an active area 131 having first unit regions 141 arranged in an array, and N main pixels 121 are located in each of the first unit regions 141. Each of the first unit regions 141 is a rectangle region. The edge effective pixels 122 are located in an edge area 132 having second unit regions 142 arranged in an array. The second unit regions 142 constitute the edge area 132, and the edge area 132 is adjacent to or connected with the tiling seam 111. At least one of the second unit regions 142 is adjacent to or connected with the tiling seam 111. M edge effective pixel or pixels 122 are located in each of the second unit regions 142. Each of the second unit regions 142 is a rectangle region. The edge area 132 is located between the active area 131 and the tiling seam 111. Each of the first unit regions 141 and each of the second unit regions 142 has substantially identical area and substantially identical brightness. N is greater than M, and both N and M are positive integers.

Referring to FIG. 1, nine (N=9) main pixels 121 are located in each of the first unit regions, and three (M=3) edge effective pixels 122 are located in each of the second unit regions 142. N=9 and M=3 are merely illustrative examples, and the present disclosure is not limited thereto. The edge effective pixels 122 are located farther away from the tiling seam 111 and closer to the first unit regions 141.

Furthermore, in FIG. 1, in the active area 131, the pixel pitch P1 of the main pixels 121 located farther away from the tiling seam 111 is smaller than the pixel pitch P2 of the main pixels 121 located closer to the tiling seam 111.

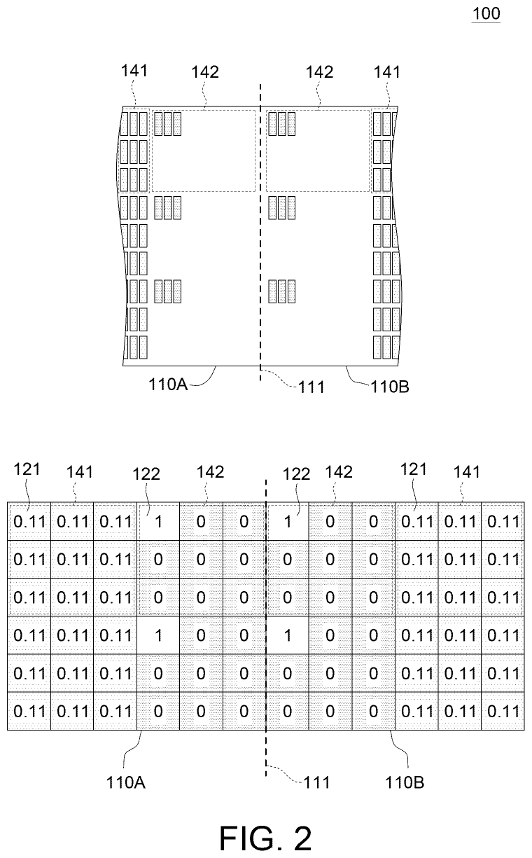

FIG. 2 illustrates a schematic diagram of brightness compensation of the tiled display according to one embodiment of the present disclosure. The brightness of the present embodiment is normalized and ranges from 0 to 1. Each of the first and second unit regions 141, 142 is a rectangle region. As shown in FIG. 2, when the brightness of all nine main pixels 121 in the first unit region 141 is adjusted to 0.11, the effective brightness of the first unit region 141 is approximately 0.11×9=0.99. Among the M edge effective pixels 122 in the second unit region 142, one edge effective pixel 122 which is located in a corner of the second unit region 142 has its brightness adjusted to 1 while other region where no eight edge effective pixel 122 is located has brightness 0. Thus, the effective brightness of the second unit region 142 is 1+(0×8)=1. Thus, in FIG. 2, after brightness compensation, the effective brightness of the first unit region 141 may be regarded as substantially equal to or very close to the effective brightness of the second unit region 142. Accordingly, the conventional problem of “visual discontinuity” can be alleviated. Alternatively, in other examples, among the M edge effective pixels 122 in the second unit region 142, more than one edge effective pixel 122 may have a brightness adjustment other than 0, while the remaining edge pixels have a brightness adjustment of 0, such that the effective brightness of the second unit region 142 is approximately 1.

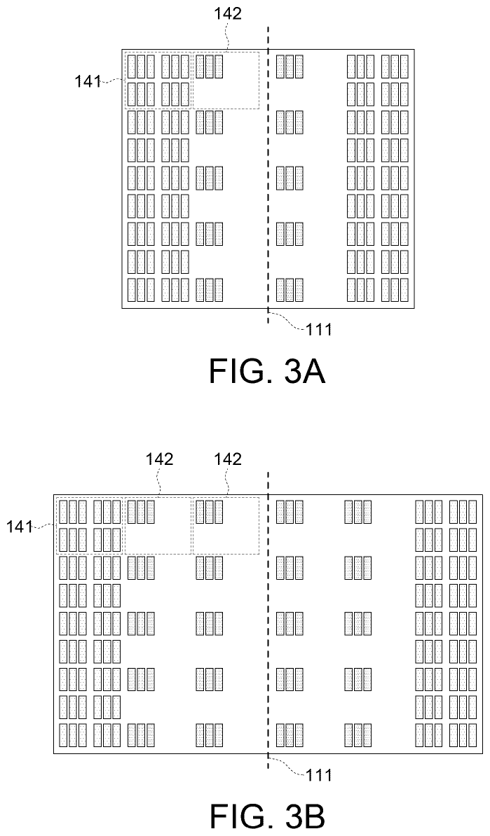

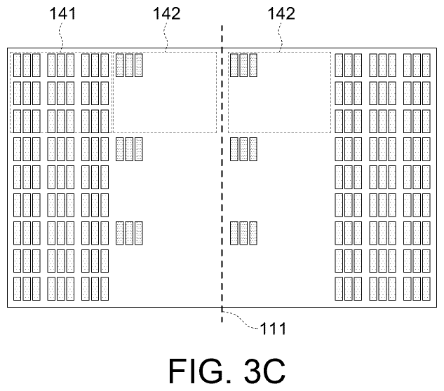

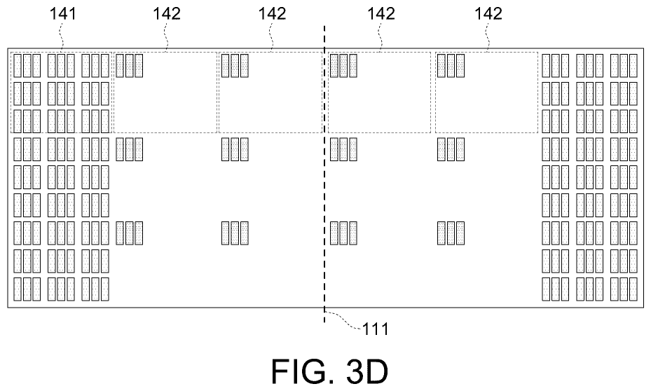

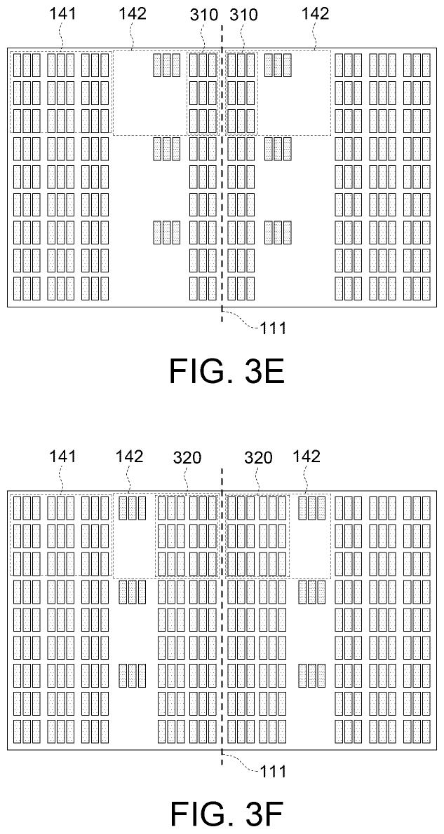

FIGS. 3A to 3F illustrate tiled displays according to the embodiments of the present disclosure.

As shown in FIG. 3A, four main pixels 121 are located in the first unit region 141. Assuming that the brightness of each of these four main pixels 121 is adjusted as 0.25, the effective brightness of the first unit region 141 is approximately 0.25×4=1. The edge area includes one column of second unit regions 142. The second unit regions 142 are arranged in an array including only one column. Only one edge effective pixel 122 is located in the second unit region 142. In the second unit region 142, if edge effective pixel 122 has its brightness adjusted to 1, the effective brightness of the second unit region 142 is 1+(0×3)=1. That is, in the second unit region 142 of the edge area, one edge effective pixel 122 is lit to compensate the second unit region 142. Therefore, in FIG. 3A, after brightness compensation, the effective brightness of the first unit region 141 may be regarded as substantially equal to or very close to the effective brightness of the second unit region 142.

As shown in FIG. 3B, four main pixels 121 are located in the first unit region 141. Assuming that the brightness of these four main pixels 121 is adjusted to 0.25, the effective brightness of the first unit region 141 is approximately 0.25×4=1. The edge area includes two columns of second unit regions 142. The second unit regions 142 are arranged in the array including two columns. Among the edge effective pixel 122 of the second unit region 142, if the edge effective pixel 122 has its brightness adjusted to 1, the effective brightness of the second unit region 142 is 1+(0×3)=1. That is, in each second unit region 142 of the edge area, one edge effective pixel 122 is lit to compensate the second unit region 142. Therefore, in FIG. 3B, after brightness compensation, the effective brightness of the first unit region 141 may be regarded as substantially equal to or very close to the effective brightness of the second unit region 142.

As shown in FIG. 3C, nine main pixels 121 are located in the first unit region 141. Assuming that the brightness of each of these nine main pixels 121 is adjusted to 0.11, the effective brightness of the first unit region 141 is approximately 0.11×9=0.99. The edge area includes one column of second unit regions 142. The second unit regions 142 are arranged in an array including only one column. Only one edge effective pixel 122 is located in the second unit region 142. In the second unit region 142, if edge effective pixel 122 has its brightness adjusted to 1, the effective brightness of the second unit region 142 is 1+(0×8)=1. That is, in the second unit region 142 of the edge area, one edge effective pixel 122 is lit for compensation. Therefore, in FIG. 3C, after brightness compensation, the effective brightness of the first unit region 141 may be regarded as substantially equal to or very close to the effective brightness of the second unit region 142.

As shown in FIG. 3D, nine main pixels 121 are located in the first unit region 141. Assuming that the brightness of each of these nine main pixels 121 is adjusted to 0.11, the effective brightness of the first unit region 141 is approximately 0.11×9=0.99. The edge area includes two columns of second unit regions 142. The second unit regions 142 are arranged in an array including two columns. Only one edge effective pixel 122 is located in the second unit region 142. In the second unit region 142, if the edge effective pixel 122 has its brightness adjusted to 1, the effective brightness of the second unit region 142 is 1+(0×8)=1. That is, in the second unit region 142 of the edge area, one edge effective pixel 122 is lit for compensation. Therefore, in FIG. 3D, after brightness compensation, the effective brightness of the first unit region 141 may be regarded as substantially equal to or very close to the effective brightness of the second unit region 142.

As shown in FIG. 3E, nine main pixels 121 are located in the first unit region 141. Assuming that the brightness of each of these nine main pixels 121 is adjusted to 0.11, the effective brightness of the first unit region 141 is approximately 0.1×9=0.99. The edge area includes one column of second unit regions 142. The second unit regions 142 are arranged in an array including only one column, and the second unit region 142 has a black region 310. The black region 310 is adjacent to the tiling seam 111. There is no edge effective pixel located in the black region 310 or edge effective pixels in the black region 310 are set to be non-emissive (that is, the black region 310 does not emit light). It is assumed that the width of the black region 310 is equal to the width of one pixel. The area of the second unit region 142 is equal to the area of 9 pixels. In the second unit region 142, if edge effective pixel 122 has its brightness adjusted to 1, the effective brightness of the second unit region 142 is 1+(0×8)=1. That is, in the second unit region 142 of the edge area, one edge effective pixel 122 is lit to compensate the second unit region 142 (including compensating the black region 310). Therefore, in FIG. 3E, after brightness compensation, the effective brightness of the first unit region 141 may be regarded as substantially equal to or very close to the effective brightness of the second unit region 142.

As shown in FIG. 3F, nine main pixels 121 are located in the first unit region 141. Assuming that the brightness of each of these nine main pixels 121 is adjusted to 0.11, the effective brightness of the first unit region 141 is approximately 0.11×9=0.99. The edge area includes one column of second unit regions 142. The second unit regions 142 are arranged in an array including only one column, and the second unit region 142 has a black region 320. The black region 320 does not emit light. It is assumed that the width of the black region 320 is equal to the width of two pixels. That is, the area of the second unit region 142 is equal to the area of 9 pixels. In second unit region 142, if one edge effective pixel 122 has its brightness adjusted to 1, the effective brightness of the second unit region 142 is 1+(0×8)=1. That is, in the second unit region 142 of the edge area, one edge effective pixel 122 is lit to compensate the second unit region 142 (including compensating the black region 320). Therefore, in FIG. 3F, after brightness compensation, the effective brightness of the first unit region 141 may be regarded as substantially equal to or very close to the effective brightness of the second unit region 142.

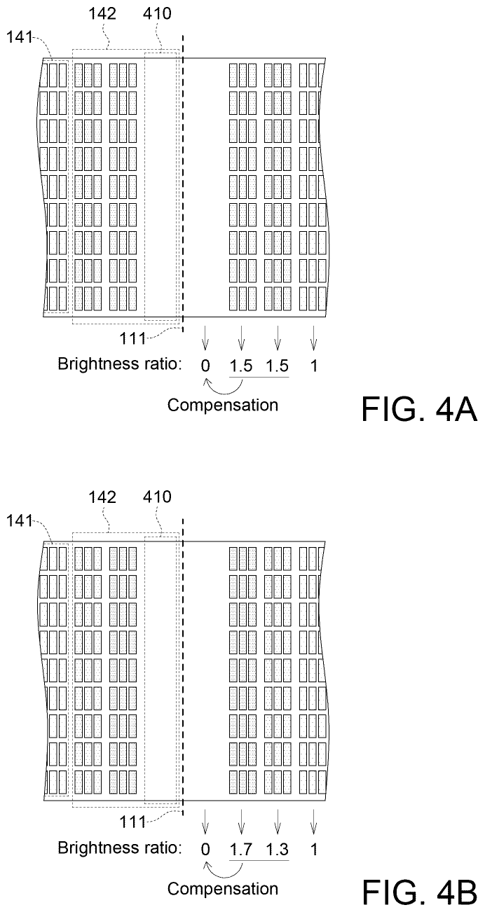

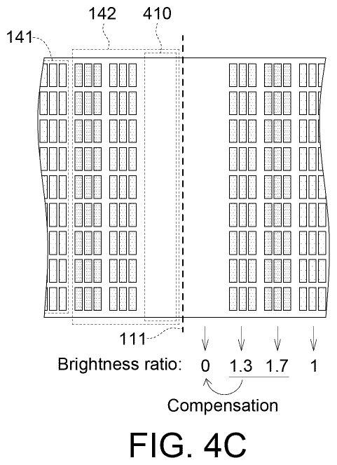

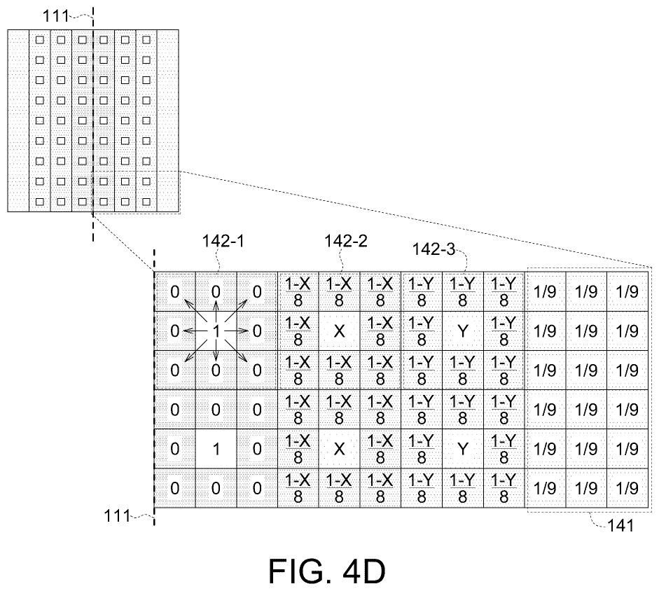

FIGS. 4A to 4D illustrate another schematic diagram of brightness compensation of the tiled display according to embodiments of the present disclosure.

As shown in FIG. 4A, the brightness ratio of one main pixel column of the first unit region 141 is adjusted to 1. The second unit region 142 of the edge area includes two columns of edge effective pixels (two edge effective pixel columns) and a black region 410, and the black region 410 does not emit light. The brightness ratios of the two columns of edge effective pixels of each second unit region 142 are adjusted to 1.5 and 1.5, respectively, to compensate the black region 410. Therefore, the effective brightness of each column region of the second unit region 142 is (1.5+1.5+0)/3=1. Accordingly, in FIG. 4A, after brightness compensation, the effective brightness of the first unit region 141 may be regarded as substantially equal to or very close to the effective brightness of the second unit region 142.

As shown in FIG. 4B, the brightness ratio of one main pixel column of the first unit region 141 is adjusted to 1. The second unit region 142 of the edge area includes two columns of edge effective pixels (two edge effective pixel columns) and a black region 410, and the black region 410 does not emit light. The brightness ratios of the two columns (first column and second column) of edge effective pixels of each second unit region 142 are adjusted to 1.7 and 1.3, respectively, to compensate the black region 410. The tiling seam, the black region 410, the first column, the second column and the active area are arranged in sequence along a first direction. Therefore, the effective brightness of each column region of the second unit region 142 is (1.7+1.3+0)/3=1. Accordingly, in FIG. 4B, after brightness compensation, the effective brightness of the first unit region 141 may be regarded as substantially equal to or very close to the effective brightness of the second unit region 142.

As shown in FIG. 4C, the brightness ratio of one main pixel column of the first unit region 141 is adjusted to 1. The second unit region 142 of the edge area includes two columns of edge effective pixels (two edge effective pixel columns) and a black region 410, and the black region 410 does not emit light. The brightness ratios of the two columns (first column and second column) of edge effective pixels of each second unit region 142 are adjusted to 1.3 and 1.7, respectively, to compensate the black region 410. The tiling seam, the black region 410, the first column, the second column and the active area are arranged in sequence along a first direction. Therefore, the effective brightness of each column region of the second unit region 142 is (1.3+1.7+0)/3=1. Accordingly, in FIG. 4C, after brightness compensation, the effective brightness of the first unit region 141 may be regarded as substantially equal to or very close to the effective brightness of the second unit region 142.

As shown in FIG. 4D, the brightness of the first unit region 141 is adjusted to 1, and the brightness of each main pixel 121 of the first unit region 141 is adjusted to 1/9. The second unit regions are arranged in the array including a first column, a second column and a third column. The tiling seam 111, the first column, the second column, the third column and the active area are arranged in sequence along a first direction. The edge area includes second unit regions 142_1 of the first column, second unit regions 142_2 of the second column, and second unit regions 142_3 of the third column. Nine edge effective pixels (M=9) are located in each of the second unit regions 142_1 to 142_3. In the second unit region 142_1 of the first column, if one edge effective pixel 122 has its brightness adjusted to 1 while other eight edge effective pixels 122 have their brightness adjusted to 0, the effective brightness of the second unit region 142_1 is 1+(0×8)=1. In the second unit region 142_2 of the second column, if one edge effective pixel 122 has its brightness adjusted to x (0<X<1), and other eight edge effective pixels 122 have their brightness adjusted to (1−X)/(M−1)=(1−X)/8, the effective brightness of the second unit region 142_2 is X+8×(1−X)/8=1. In the second unit region 142_3 of the third column, if one edge effective pixel 122 has its brightness adjusted to y (0<Y<1, and X may be equal to or not equal to Y), and other eight edge effective pixels 122 have their brightness adjusted to (1−Y)/(M−1)=(1−Y)/8, the effective brightness of the second unit region 142_3 is Y+8×(1−Y)/8=1. Therefore, in FIG. 4D, after brightness compensation, the effective brightness of the first unit region 141 may be regarded as substantially equal to or very close to the effective brightness of the second unit region 142.

From the above, through brightness compensation, the effective brightness of the first unit region of the active area may be regarded as substantially equal to or very close to the effective brightness of the second unit region of the edge area. Therefore, the problem of “visual discontinuity” in the conventional technology can be alleviated.

Although many specific details may have been described in the present disclosure, these should not be construed as limitations on the scope of the claimed disclosure, but rather as descriptions of the characteristics of particular embodiments. In the present specification, certain features described in the context of a single embodiment may also be implemented in combination in a single embodiment. Conversely, various features described in the context of a single embodiment may also be implemented individually or in any suitable subcombination in multiple embodiments. In addition, although certain features may initially be described as operating in particular combinations or may initially be described as such combinations, in some cases one or more features may be omitted from the combination, and the described combination may be directed to a subcombination or a variation of a subcombination. Likewise, although operations may be depicted in a specific order in the drawings, this should not be construed as requiring the operations to be performed in the specific order shown or in sequential order, or that all depicted operations must be performed to achieve the desired result.

Although the above embodiments of the present disclosure disclose only some examples and implementations, based on the disclosures herein, modifications, alterations, and enhancements may be made to the described examples and implementations as well as to other implementations.

In conclusion, although the present disclosure has been disclosed above by way of embodiments, these are not intended to limit the present disclosure. A person having ordinary skill in the art may make various changes and refinements without departing from the spirit and scope of the present disclosure. Therefore, the scope of protection of the present disclosure shall be based on the appended claims.

What is claimed is:

1. A tiled display, comprising:
a plurality of display panels, wherein a tiling seam is located between the display panels and at least one of the display panels comprises:
a plurality of main pixels located in an active area having a plurality of first unit regions arranged in an array, wherein N main pixels are located in each of the first unit regions, and N is a positive integer; and
a plurality of edge effective pixels located in an edge area having a plurality of second unit regions arranged in an array, wherein the edge area is between the active area and the tiling seam, M edge effective pixel or pixels are located in each of the second unit regions, M is a positive integer, N is greater than M, each of the first unit regions and each of the second unit regions have a substantially identical area and a substantially identical brightness, and the substantially identical brightness is not zero.

2. The tiled display according to claim 1, wherein a pixel pitch of the main pixels located farther away from the tiling seam is smaller than a pixel pitch of the main pixels located closer to the tiling seam.

3. The tiled display according to claim 1, wherein:
a brightness of each of the main pixels in one of the first unit regions is adjusted to be substantially identical; and
in one of the second unit regions, a brightness of at least one of the edge effective pixels is adjusted to be not zero, while a brightness of each of the remaining edge effective pixels is adjusted to be zero.

4. The tiled display according to claim 3, wherein in the one of the second unit regions, the remaining edge effective pixels is located in a black region of the one of the second unit regions.

5. The tiled display according to claim 4, wherein each of the second unit regions is a rectangle region, the remaining edge effective pixels is located between the at least one of the edge effective pixels and the tiling seam.

6. The tiled display according to claim 5, wherein the at least one of the edge effective pixels is in a corner of the rectangle region.

7. The tiled display according to claim 1, wherein each of the edge effective pixels is not located in a black region of one the second unit regions.

8. The tiled display according to claim 7, wherein the black region of the one of the second unit regions is between the M edge effective pixels of the one of the second unit regions and the tiling seam.

9. The tiled display according to claim 1, wherein each of the second unit regions is a rectangle region, and the M edge effective pixel is in a corner of the rectangle region.

10. The tiled display according to claim 1, wherein the second unit regions constitute the edge area so that the edge area is connected with the tiling seam.

11. The tiled display according to claim 10, wherein at least one of the second unit regions is connected with the tiling seam.

12. A tiled display, comprising:
a first display panel and a second display panel, wherein a tiling seam is located between the first display panel and the second display panel, and each of the first display panel and the second display panel comprises:
a plurality of main pixels located in an active area having a plurality of first unit regions arranged in an array, wherein N main pixels are located in each of the first unit regions, and N is a positive integer; and
a plurality of edge effective pixels located in an edge area having a plurality of second unit regions arranged in an array, wherein the edge area is between the active area and the tiling seam, M edge effective pixel or pixels are located in each of the second unit regions, M is a positive integer, N is greater than M, and each of the first unit regions and each of the second unit regions have a substantially identical area and a substantially identical brightness.

13. The tiled display according to claim 12, wherein each of the second unit regions is a rectangle region, and the M edge effective pixel is in a corner of the rectangle region.

14. A tiled display, comprising:
a plurality of display panels, wherein a tiling seam is located between the display panels and at least one of the display panels comprises:
a plurality of main pixels located in an active area having a plurality of first unit regions arranged in an array, wherein N main pixels are located in each of the first unit regions, and N is a positive integer; and
a plurality of edge effective pixels located in an edge area having a plurality of second unit regions arranged in an array, wherein the edge area is between the active area and the tiling seam, M edge effective pixel or pixels are located in each of the second unit regions, M is a positive integer, and each of the first unit regions and each of the second unit regions have a substantially identical area and a substantially identical brightness, wherein:
a brightness of each of the main pixels of one of the first unit region is adjusted to be substantially identical;
the second unit regions includes a first column, a second column and a third column, and the tiling seam, the first column, the second column, the third column and the active area are arranged in sequence along a first direction;
in one of the second unit regions in the first column, a brightness of one of the edge effective pixels is adjusted to be 1, while a brightness of each of the remaining edge effective pixels is adjusted to be zero;
in one of the second unit regions in the second column, a brightness of one of the edge effective pixels is adjusted to be X, 0<X<1, while a brightness of each of the remaining edge effective pixels is adjusted to be (1−X)/(M−1); and
in one of the second unit regions in the third column, a brightness of one of the edge effective pixels is adjusted to be Y, 0<Y<1, while a brightness of each of the remaining edge effective pixels is adjusted to be (1−Y)/(M−1).

15. The tiled display according to claim 14, wherein X is not equal to Y.
